(19) United States
(12) Patent Application Publication
(10) Pub. No.: US 2006/0226121 A1
(43) Pub. Date: Oct. 12, 2006

(54) Etching method

(75) Inventor: Nobuo Aoi, Hyogo (JP)

Correspondence Address: NIXON PEABODY, LLP, 401 9TH STREET, NW, SUITE 900, WASHINGTON, DC, 20004-2128, US

(73) Assignee: Matsushita Electric Industrial Co., Ltd., Osaka (JP)

(21) Appl. No.: 11/455,800

(22) Filed: Jun. 20, 2006

Related U.S. Application Data
(62) Division of application No. 10/643,896, filed on Aug. 20, 2003.
Application No. 10/643,896 is a division of application No. 09/492,841, filed on Jan. 27, 2000, now abandoned.

(30) Foreign Application Priority Data
Jan. 27, 1999 (JP) 11-017916

(51) Int. Cl. C23F 1/00; H01L 21/302

(52) U.S. Cl. 216/67; 438/689

(57) ABSTRACT

An interlayer insulating film composed of an organic compound film containing an organic component as a main constituent is deposited on a semiconductor substrate. Then, etching is performed with respect to the interlayer insulating film by using a plasma derived from an etching gas containing an ammonia gas as a main constituent. As a result, active hydrogen is generated in the plasma derived from the ammonia gas to decompose the organic component into hydrogen cyanide, whereby etching proceeds. Since a surface of the organic compound film is efficiently nitrided by nitrogen generated from the ammonia gas, the sidewalls of a depressed portion in the organic compound film are protected so that an excellent anisotropic property is provided. Since the etching gas does not contain a component which oxidizes the organic compound film, the problem does not occur that a gas is generated from the organic compound film in a subsequent heat treatment process.

### BACKGROUND OF THE INVENTION

The present invention relates to an etching method and, more particularly to anisotropic etching performed with respect to an interlayer insulating film composed of an organic compound film containing an organic component as a main constituent or to an interlayer insulating film composed of an organic-inorganic hybrid film containing an organic component and a silica component as main constituents.

As the integration density of a semiconductor integrated circuit has increased, an increased wiring delay time resulting from an increase in wire-to-wire capacitance, which is a parasitic capacitance between metal wires, has presented an obstacle to the implementation of a semiconductor integrated circuit with higher performance. The wiring delay time is a so-called RC delay which is proportional to the product of the resistance of the metal wire and the wire-to-wire capacitance.

To reduce the wiring delay time, therefore, it is necessary to reduce the resistance of the metal wire or the wire-to-wire capacitance.

As methods of reducing the wire-to-wire capacitance, the reduction of the dielectric constant of an interlayer insulating film formed between the metal wires has been considered and the use of a material different from that used to compose a conventional silicon oxide film as the interlayer insulating film has been examined.

In a semiconductor integrated circuit with 0.25-μm design rules, a fluorine-containing silicon oxide film composed of a silicon oxide film containing fluorine is currently used as an interlayer insulating film. Since the dielectric constant of the fluorine-containing silicon oxide film is in the range of −3.3 to 3.9 and smaller than the dielectric constant of the conventional silicon oxide film in the range of 4.2 to 4.5, the use of the fluorine-containing silicon oxide film has been reported to be effective in reducing the wire-to-wire capacitance and reducing the wiring delay time.

However, since further scaling down of the semiconductor integrated circuit is self-evident, the use of an interlayer insulating film having a dielectric constant of 3.0 or less is considered to be essential to the implementation of a practical processing speed in a semiconductor integrated circuit with 0.13-μm or smaller design rules.

As examples of an interlayer insulating film having a dielectric constant much lower than that of the fluorine-containing silicon oxide film, a low-dielectric-constant SOG (spin-on-glass) film, an organic compound film, and a porous film are under study. If the currently known interlayer insulating films are studied in terms of materials' physical properties, the organic-compound film is promising because of its low dielectric constant.

Of the materials composing organic compound films, perfluorocarbon polymers each having a fluorine-carbon bond have the lowest dielectric constants, of which the lowermost one is on the order of 1.9.

As a typical method of forming perfluorocarbon, a method of depositing perfluorocarbon by plasma CVD has been reported. In general, an organic compound film formed of perfluorocarbon by plasma CVD as a material is termed in most cases an amorphous fluorocarbon (a-CF) film.

To improve heat resistance and adhesion of an organic compound film, there has also been studied an organic-inorganic hybrid film composed of a copolymer of an organic component and a silica component.

However, since the organic compound film and the organic-inorganic hybrid film are highly susceptible to oxidization, the problem is encountered that degassing occurs in a heat treatment process subsequently performed. Specifically, the patterning of the organic compound film is normally conducted by reactive ion etching using an etching gas containing oxygen gas as a main constituent. During etching, however, the quality of the organic compound film is degraded by oxygen because of high reactivity of the organic compound film to oxygen. That is, active oxygen radicals generated in the plasma oxidize the organic compound film to generate an unstable carbonyl compound. Since the carbonyl compound generated is taken in by the organic compound film, the carbonyl compound within the organic compound film is thermally decomposed in the heat treatment process subsequently performed, so that a gas is generated from the organic compound film. When the gas is generated from the organic compound film, faulty filling occurs in filling a metal film in the depressed portion of the patterned organic compound film, leading to the problem of increased connection resistance.

To prevent the problem, there has been examined the use of an etching gas containing nitrogen gas and hydrogen gas as main constituents instead of the etching gas containing oxygen gas as the main constituent. In this case, however, another problem occurs that etching should be performed at a low temperature of about −50° C. in order to improve the anisotropic property of etching.

In the case of using the etching gas containing nitrogen gas and hydrogen gas as the main constituents to etch the organic-inorganic hybrid film containing the organic component and the silica component as the main constituents, it is difficult to etch the silica component so that etch residues and particles are generated to cause still another problem.

### SUMMARY OF THE INVENTION

In view of the foregoing, an object of the present invention is to allow anisotropic etching to be performed with respect to an interlayer insulating film composed of anorganic compound film containing an organic component as a main constituent or to an interlayer insulating film composed of anorganic-inorganic hybrid film containing an organic component and a silica component as main constituents.

A first etching method according to the present invention comprises the step of performing anisotropic etching with respect to an interlayer insulating film composed of an organic compound film containing an organic component as a main constituent by using a plasma derived from an etching gas containing an ammonia gas as a main constituent.

In accordance with the first etching method, active hydrogen is generated in the plasma derived from the ammonia gas to decompose the organic component into hydrogen cyanide-so that etching with respect to the organic compound film proceeds. In this case, since a surface of the organic compound film is efficiently nitrided by nitrogen generated from the ammonia gas, the sidewalls of a depressed portion in the organic compound film are protected so that an excellent anisotropic property is provided.

Moreover, since the etching gas does not contain a component which oxidizes the organic compound film, the organic-compound film is not oxidized. This prevents the problem of a gas generated from the organic compound film in the subsequent heat treatment process.

Thus, the first etching method allows highly anisotropic etching to be performed with respect to the organic compound film without incurring the degradation thereof.

A second etching method according to the present invention comprises the step of performing anisotropic etching with respect to an interlayer insulating film composed of an organic compound film containing anorganic component as a main constituent by using a plasma derived from an etching gas containing a carbon dioxide gas as a main constituent.

In accordance with the second etching method, CO ions contained in the plasma derived from the carbon dioxide gas contribute to etching so that anisotropic etching with respect to the organic compound film proceeds.

Moreover, since the etching gas containing the carbon dioxide gas as the main constituent is used, the amount of active oxygen is smaller than in the case of using the etching gas containing the oxygen gas as the main constituent, while CO radicals generated consume excess active oxygen. Accordingly, the active oxygen contributes only to the etching of the organic compound film so that the organic compound film is less likely to, be oxidized. This prevents the problem of a gas generated from the organic compound film in the subsequent heat treatment process.

Thus, the second etching method allows highly anisotropic etching to be performed with respect to the organic compound film without incurring the degradation thereof.

In the first or second etching method, the etching gas preferably contains an inert gas. The arrangement improves-both the anisotropic property of etching and the etching rate.

A third etching method according to the present invention comprises the step of performing anisotropic etching with respect to an interlayer insulating film composed of an organic compound film containing an organic component as a main constituent by using a plasma derived from an etching gas containing a hydrogen gas, a nitrogen gas, and an inert gas as main constituents.

In accordance with the third etching method, hydrogen contained in the etching gas is activated and the resulting active hydrogen decomposes the organic component into hydrogen cyanide, so that etching with respect to the organic compound film proceeds. In this case, since a surface of the organic compound film is efficiently nitrided by the nitrogen gas, the sidewalls of a depressed portion in the organic compound film are protected so that an excellent anisotropic property is provided.

Since the etching gas does not contain a component which oxidizes the organic compound film, the organic compound film is not oxidized. This prevents the problem of a gas generated from the organic compound film in the subsequent heat treatment process.

The sputtering effect of the inert gas contained in the etching gas improves both the anisotropic property of etching and the etching rate.

Thus, the third etching method allows highly anisotropic etching to be performed with respect to the organic-inorganic hybrid film without incurring the degradation thereof.

A fourth etching method according to the present invention comprises the step of performing anisotropic-etching with respect to an interlayer insulating film composed of an organic-inorganic hybrid film containing an organic component and a silica component as main constituents by using a plasma derived from an etching gas containing an ammonia gas and a fluorine gas as main constituents.

In accordance with the fourth etching method, active hydrogen generated from the ammonia gas decomposes the organic component in the organic-inorganic hybrid film into hydrogen cyanide, while fluorine decomposes the inorganic component in the organic-inorganic hybrid film, so that etching with respect to the organic-inorganic hybrid film proceeds.

In the process of etching, a surface of the organic-inorganic hybrid film is efficiently nitrided by nitrogen generated from the ammonia gas so that the sidewalls of a depressed portion in the organic-inorganic hybrid film are protected and therefore an excellent anisotropic property is provided.

Since the etching gas does not contain a component which oxidizes the organic compound film, the organic-inorganic hybrid film is not oxidized. This prevents the problem of a gas generated from the organic-inorganic hybrid film in the subsequent heat treatment process.

Thus, the fourth etching method allows highly anisotropic etching to be performed with respect to the organic-inorganic hybrid film without incurring the degradation thereof.

A fifth etching method according to the present invention comprises the step of performing anisotropic etching with respect to an interlayer insulating film composed of an organic-inorganic hybrid film containing an organic component and a silica component as main constituents by using a plasma derived from an etching gas containing a hydrogen gas, a nitrogen gas, and a fluorine gas as main constituents.

In accordance with the fifth etching method, hydrogen contained in the etching gas is activated and the resulting active hydrogen decomposes the organic component in the organic-inorganic hybrid film into hydrogen cyanide, while fluorine decomposes the inorganic component in the organic-inorganic hybrid film, so that etching with respect to the organic-inorganic hybrid film proceeds.

In the process of etching, a surface of the organic-inorganic hybrid film is efficiently nitrided by nitrogen so that the sidewalls of a depressed portion in the organic-inorganic hybrid film are protected and therefore an excellent anisotropic property is provided.

Since the etching gas does not contain a component which oxidizes the organic compound film, the organic-inorganic hybrid film is not oxidized. This prevents the problem of a gas generated from the organic-inorganic hybrid film in the subsequent heat treatment process.

Thus, the fifth etching method allows highly anisotropic etching to be performed with respect to the organic-inorganic hybrid film without incurring the degradation thereof.

A sixth etching method according to the present invention comprises the step of performing anisotropic etching with respect to an interlayer insulating film composed of an organic-inorganic hybrid film containing an organic component and a silica component as main constituents by using a plasma derived from an etching gas containing a hydrogen gas and a nitrogen trifluoride gas as main constituents.

In accordance with the sixth etching method, hydrogen contained in the etching gas is activated and the resulting active hydrogen decomposes the organic component in the organic-inorganic hybrid film into hydrogen cyanide, while fluorine generated from the nitrogen trifluoride gas decomposes the inorganic component in the organic-inorganic hybrid film, so that etching with respect to the organic-inorganic hybrid film proceeds.

In the process of etching, a surface of the organic-inorganic hybrid film is efficiently nitrided by nitrogen generated from the nitrogen trifluoride gas so that the sidewalls of a depressed portion in the organic-inorganic hybrid film are protected and therefore an excellent anisotropic property is provided.

Since the etching gas does not contain a component which oxidizes the organic compound film, the organic-inorganic hybrid film is not oxidized. This prevents the problem of a gas generated from the organic-inorganic hybrid film in the subsequent heat treatment process.

Thus, the sixth etching method allows highly anisotropic etching to be performed with respect to the organic-inorganic hybrid film without incurring the degradation thereof.

A seventh etching method according to the present invention comprises the step of performing anisotropic etching with respect to an interlayer insulating film composed of an organic-inorganic hybrid film containing an organic component and a silica component as main constituents by using a plasma derived from an etching gas containing a nitrogen gas and a hydrogen fluoride gas as main constituents.

In accordance with the seventh etching method, active hydrogen generated from the hydrogen fluoride gas decomposes the organic component in the organic-inorganic hybrid film into hydrogen cyanide, while fluorine generated from the hydrogen fluoride gas decomposes the inorganic component in the organic-inorganic hybrid film, so that etching with respect to the organic-inorganic hybrid film proceeds.

In the process of etching, a surface of the organic-inorganic hybrid film is efficiently nitrided by nitrogen so that the sidewalls of a depressed portion in the organic-inorganic hybrid film are protected and therefore an excellent anisotropic property is provided.

Since the etching gas does not contain a component which oxidizes the organic compound film, the organic-inorganic hybrid film is not oxidized. This prevents the problem of a gas generated from the organic-inorganic hybrid film in the subsequent heat treatment process.

Thus, the seventh etching method allows highly anisotropic etching to be performed with respect to the organic-inorganic hybrid film without incurring the degradation thereof.

An eighth etching method according to the present invention comprises the step of performing anisotropic etching with respect to an interlayer insulating film composed of an organic-inorganic hybrid film containing an organic component and a silica component as main constituents by using a plasma derived from an etching gas containing a nitrogen gas and a fluorinated hydrocarbon gas as main constituents.

In accordance with the eighth etching method, active hydrogen generated from the fluorinated hydrocarbon gas decomposes the organic component in the organic-inorganic hybrid film into hydrogen cyanide, while fluorine generated from the fluorinated hydrocarbon gas decomposes the inorganic component in the organic-inorganic hybrid film, so that etching with respect to the organic-inorganic hybrid film proceeds.

In the process of etching, a surface of the organic-inorganic hybrid film is efficiently nitrided by nitrogen so that the sidewalls of a depressed portion in the organic-inorganic hybrid film are protected and therefore an excellent anisotropic property is provided.

Since the etching gas does not contain a component which oxidizes the organic-inorganic hybrid film, the organic-inorganic hybrid film is not oxidized. This prevents the problem of a gas generated from the organic-inorganic hybrid film in the subsequent heat treatment process.

Thus, the eighth etching method allows highly anisotropic etching to be performed with respect to the organic-inorganic hybrid film without incurring the degradation thereof.

A ninth etching method according to the present invention comprises the step of performing anisotropic etching with respect to an interlayer insulating film composed of an organic-inorganic hybrid film containing an organic component and a silica component as main constituents by using a plasma derived from an etching gas containing a carbon dioxide gas and a fluorine gas as main constituents.

In accordance with the ninth etching method, CO ions contained in the plasma derived from the carbon dioxide gas contribute to etching so that etching with respect to the organic component in the organic-inorganic hybrid film proceeds, while fluorine decomposes the inorganic component in the organic-inorganic hybrid film, so that etching with respect to the organic-inorganic hybrid film proceeds.

Since the etching gas containing the carbon dioxide gas as the main constituent is used, the amount of active oxygen is small and generated CO radicals consume excess active oxygen. Accordingly, active oxygen contributes only to the etching of the organic component and does not oxidize the organic-inorganic compound film. This prevents the problem of a gas generated from the organic-inorganic hybrid film in the subsequent heat treatment process.

Thus, the ninth etching method allows highly anisotropic etching to be performed with respect to the organic-inorganic hybrid film without incurring the degradation thereof.

A tenth etching method according to the present invention comprises the step of performing anisotropic etching with respect to an interlayer insulating film composed of an organic-inorganic hybrid film containing an organic component and a silica component as main constituents by using a plasma derived from an etching gas containing a carbon dioxide gas and a fluorinated hydrocarbon gas as main constituents.

In accordance with the tenth etching method, CO ions contained in the plasma derived from the carbon dioxide gas contribute to etching so that etching with respect to the organic component in the organic-inorganic hybrid film proceeds, while fluorine generated from the fluorinated hydrocarbon gas decomposes the inorganic component in the organic-inorganic hybrid film, so that etching with respect to the organic-inorganic hybrid film proceeds.

Since the etching gas containing the carbon dioxide gas as the main constituent is used, the amount of active oxygen is small and the generated CO radicals consume excess active oxygen. Accordingly, the active oxygen contributes only to the etching of the organic component and does not oxidize the organic-inorganic compound film. This prevents the problem of a gas generated from the organic-inorganic hybrid film in the subsequent heat treatment process.

Thus, the tenth etching method allows highly anisotropic etching to be performed with respect to the organic-inorganic hybrid film without incurring the degradation thereof.

An eleventh etching method according to the present invention comprises the step of performing anisotropic etching with respect to an interlayer insulating film composed of an organic-inorganic hybrid film containing an organic component and a silica component as main constituents by using a plasma derived from an etching gas containing a carbon monoxide gas and a fluorine gas as main constituents.

In accordance with the eleventh etching method, CO ions contained in the plasma derived from the carbon monoxide gas contribute to etching so that etching with respect to the organic component in the organic-inorganic hybrid film proceeds, while fluorine decomposes the inorganic component in the organic-inorganic hybrid film, so that etching with respect to the organic-inorganic hybrid film proceeds.

Since the etching gas containing the carbon monoxide gas as the main constituent is used, the amount of active oxygen is small and the generated CO radicals consume excess active oxygen. Accordingly, the active oxygen contributes only to the etching of the organic component and does not oxidize the organic-inorganic compound film. This prevents the problem of a gas generated from the organic-inorganic hybrid film in the subsequent heat treatment process.

Thus, the eleventh etching method allows highly anisotropic etching to be performed with respect to the organic-inorganic hybrid film without incurring the degradation thereof.

A twelfth etching method according to the present invention comprises the step of performing anisotropic etching with respect to an interlayer insulating film composed of an organic-inorganic hybrid film containing an organic component and a silica component as main constituents by using a plasma derived from an etching gas containing a carbon monoxide gas and a fluorinated hydrocarbon gas as main constituents.

In accordance with the twelfth etching method, CO ions contained in the plasma derived from the carbon monoxide gas contribute to etching so that etching with respect to the organic component in the organic-inorganic hybrid film proceeds, while fluorine generated from the fluorinated hydrocarbon decomposes the inorganic component in the organic-inorganic hybrid film, so that etching with respect to the organic-inorganic hybrid film proceeds.

Since the etching gas containing the carbon monoxide gas as the main constituent is used, the amount of active oxygen is small and the generated CO radicals consume excess active oxygen. Accordingly, the active oxygen contributes only to the etching of the organic component and does not oxidize the organic-inorganic compound film. This prevents the problem of a gas generated from the organic-inorganic hybrid film in the subsequent heat treatment process.

Thus, the twelfth etching method allows highly anisotropic etching to be performed with respect to the organic-inorganic hybrid film without incurring the degradation thereof.

In each or the fourth to twelfth-etching methods, the etching gas preferably contains an inert gas. The arrangement improves both the anisotropic property of etching and the etching rate.

### BRIEF DESCRIPTION OF THE DRAWINGS

FIGS. 1(a) and 1(b) are cross-sectional views illustrating process steps in accordance with an etching method used commonly in the individual embodiments of the present invention.

### DETAILED DESCRIPTION OF THE INVENTION

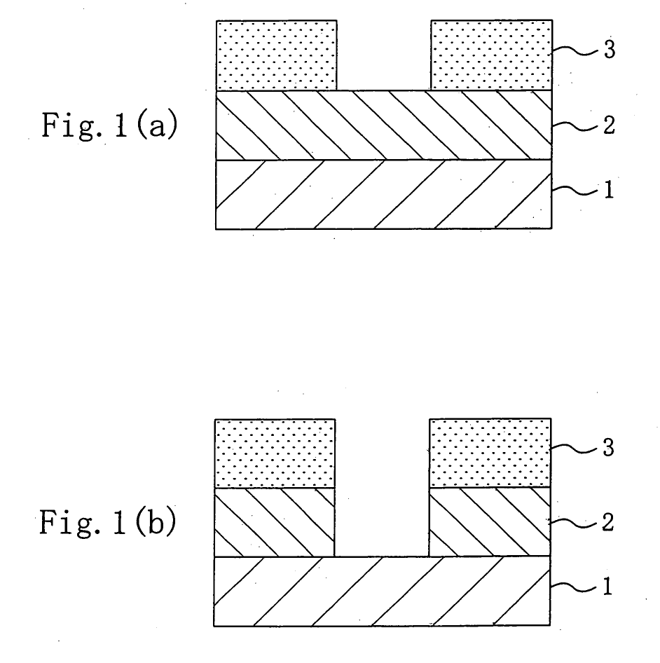

Hereinafter, an etching method according to each of the embodiments of the present invention will be described. Prior to the description, the outline of the etching method which is common to the individual embodiments will be described with reference to FIGS. 1(a) and 1(b).

First, as shown in FIG. 1(a), an interlayer insulating film 2 composed of an organic compound film containing an organic component or anorganic-inorganic hybrid film containing an organic component and a silica component as main constituents is deposited on a semiconductor substrate 1 made of silicon or the like. A resist pattern 3 having an opening in a region in which a contact hole or a wire groove is to be formed is formed on the interlayer insulating film 2.

Next, as shown in FIG. 1(b), plasma etching is performed with respect to the interlayer insulating film 2 masked with the resist pattern 3 by using a plasma derived from any of the following etching gases, thereby patterning the interlayer insulating film 2.

### Embodiment 1

A first embodiment of the present invention performs anisotropic etching with respect to an interlayer insulating film composed of an organic compound film by using a plasma derived from an etching gas containing ammonia gas as a main constituent.

As an exemplary organic compound film, there can be listed a derivative of polyaryl ether or a derivative of polyparaxylene. However, the type of the organic compound film does not particularly presents a problem.

By way of example, etching is performed in an etching apparatus using a high-density plasma as a plasma source under such conditions that pressure is 5 mTorr, the power of an RF voltage applied to a counter electrode is 3 kW, the power of a bias voltage applied to a sample to be etched is 300 W, and the flow rate of ammonia (NH₃) gas is 20 sccm.

When etching is performed with respect to the organic compound film by using the plasma derived from the etching gas containing ammonia gas as the main constituent, active hydrogen is generated in the plasma derived from ammonia gas to decompose the organic component into HCN (hydrogen cyanide), whereby etching proceeds. In this case, since a surface of the organic compound film is efficiently nitrided by nitrogen generated from ammonia gas, the sidewalls of the depressed portion in the organic compound film are protected so that an excellent anisotropic property is provided.

Since the etching gas containing ammonia gas as the main constituent does not contain a component which oxidizes the organic compound film, the organic compound film is not oxidized. As a result, the problem does not occur that a gas is generated from the organic compound film in a heat treatment process subsequently performed.

Thus, the first embodiment allows anisotropic etching to be performed with respect to the organic compound film without incurring the degradation thereof.

### Embodiment 2

A second embodiment of the present invention performs anisotropic etching with respect to an interlayer insulating film composed of an organic compound film by using a plasma derived from an etching gas containing hydrogen gas, nitrogen gas, and inert gas (such as argon gas) as main constituents.

As an exemplary organic compound film, there can be listed a derivative of polyaryl ether or a derivative of polyparaxylene. However, the type of the organic compound film does not particularly present a problem.

By way of example, etching is performed in an etching apparatus using a high-density plasma as a plasma source under such conditions that pressure is 10 mTorr, the power of an RF voltage applied to a counter electrode is 3 kW, the power of a bias voltage applied to a sample to be etched is 200 W, the flow rate of hydrogen gas is 30 sccm, the flow rate of nitrogen gas is 10 sccm, and the flow rate of argon gas is 20 sccm.

When etching is performed with respect to the organic compound film by using the plasma derived from the etching gas containing hydrogen gas, nitrogen gas, and inert gas, hydrogen contained in the etching gas is activated to decompose the organic component into HCN (hydrogen cyanide), whereby etching proceeds. In this case, since a surface of the organic compound film is efficiently nitrided by nitrogen, the sidewalls of the depressed portion in the organic compound film is protected so that an excellent anisotropic property is provided.

Since the etching gas does not contain a component which oxidizes the organic compound film, the organic compound film is not oxidized. As a result, the problem does not occur that a gas is generated from the organic compound film in a heat treatment process subsequently performed.

Moreover, the sputtering effect of argon contained in the etching gas improves the anisotropic property of etching as well as the etching rate.

Thus, the second embodiment allows anisotropic etching to be performed with respect to the organic compound film without incurring the degradation thereof.

If etching is performed by using a plasma derived from an etching containing ammonia gas as a main constituent, as in the first embodiment, it is necessary to increase the power of an RF voltage applied to a counter electrode and increase the degree of vacuum in the chamber. If the power of the RF voltage applied to the counter electrode is increased, however, an underlying film exposed at the bottom of the depressed portion in the organic compound film, e.g., a gate insulating film may suffer a serious damage. If the degree of vacuum in the chamber is increased, on the other hand, the plasma density is reduced so that the problem of a reduced etching rate arises.

By contrast, if etching is performed by using a plasma derived from an etching gas containing hydrogen gas, nitrogen gas, and inert gas as main constituents, as in the second embodiment, it is unnecessary to increase the power of an RF voltage applied to a counter electrode. As a result, there can be circumvented the situation in which an underlying film exposed at the bottom of the depressed portion in the organic compound film, e.g., a gate insulating film suffers a serious damage so that the degree of vacuum in the chamber need not be increased and the etching rate is not reduced.

Moreover, the sputtering effect of argon contained in the etching gas improves the etching rate.

### Embodiment 3

A third embodiment of the present invention performs anisotropic etching with respect to an interlayer insulating film composed of an organic compound film by using a plasma derived from an etching gas containing ammonia gas and inert gas (such as argon gas) as main constituents.

As an exemplary organic compound film, there can be listed a derivative of polyaryl ether or a derivative of polyparaxylene. However, the type of the organic compound film does not particularly present a problem.

By way of example, etching is performed in an etching apparatus using a high-density plasma as a plasma source under such conditions that pressure is 30 mTorr, the power of an RF voltage applied to a counter electrode is 3 kW, the power of a bias voltage applied to a sample to be etched is 200 W, the flow rate of ammonia gas is 30 sccm, and the flow rate of argon gas is 20 sccm.

When etching is performed with respect to the organic compound film by using the plasma derived from the etching gas containing ammonia gas and inert gas, active hydrogen is generated from ammonia in the plasma to decompose the organic component into HCN, whereby etching proceeds. In this case, since a surface of the organic compound film is efficiently nitrided by nitrogen, the sidewalls of the depressed portion in the organic compound film is protected so that an excellent anisotropic property is provided.

Since a component which oxidizes the organic compound film is not contained in the etching gas, the organic compound film is not oxidized. As a result, the problem does not occur that a gas is generated from the organic compound film in a heat treatment process subsequently performed.

Moreover, the sputtering effect of argon contained in the etching gas enables high-speed etching having an excellent anisotropic property.

Thus, the third embodiment allows anisotropic etching to be performed with respect to the organic compound film without incurring the degradation thereof.

In the case of using an etching gas containing a hydrogen gas and a nitrogen gas as main constituents as in the second embodiment, the problems of lower nitriding efficiency and a lower etching rate than in the case of using an etching gas containing ammonia as a main constituent are encountered. However, the third embodiment has solved these problems to provide higher nitriding efficiency and a higher etching rate than in the second embodiment.

### Embodiment 4

A fourth embodiment of the present invention performs anisotropic etching with respect to an interlayer insulating film composed of an organic compound film by using a plasma derived from an etching gas containing a carbon dioxide gas as a main constituent.

As an exemplary organic compound film, there can be listed a derivative of polyaryl ether or a derivative of polyparaxylene. However, the type of the organic compound film does not particularly present a problem.

By way of example, etching is performed in an etching apparatus using a high-density plasma as a plasma source under such conditions that pressure is 5 mTorr, the power of an RF voltage applied to a counter electrode is 3 kW, the power of a bias voltage applied to a sample to be etched is 300 W, and the flow rate of carbon dioxide gas is 20 sccm.

According to the fourth embodiment, etching is performed by using the plasma derived from the etching gas containing carbon dioxide gas as the main constituent so that CO ions contained in the plasma derived from carbonic gas contribute to anisotropic etching. As a result, anisotropic etching with respect to the organic compound film proceeds.

Since the etching gas containing carbon dioxide gas as the main constituent is used, the amount of active oxygen is smaller than in the case of using an etching gas containing oxygen gas (oxygen plasma) as a main constituent. Since generated CO radicals consume excess active oxygen, active oxygen contributes to only the etching of the organic compound film. For such reasons, the oxidation of the organic compound film is suppressed.

Thus, the fourth embodiment allows anisotropic etching to be performed with respect to the organic compound film without incurring the degradation thereof.

If inert gas such as argon gas is added to the etching gas, both the anisotropic property of etching and the etching rate can be improved.

### Embodiment 5

A fifth embodiment of the present invention performs anisotropic etching with respect to an interlayer insulating film composed of an organic-inorganic hybrid film by using a plasma derived from an etching gas containing ammonia gas and fluorine gas as main constituents.

As an exemplary organic-inorganic hybrid film, there can be listed a siloxane-containing fluorinated organic compound film deposited by plasma CVD by using, as raw material gas, a gas mixture of C₄H₈ for C₁₀F₁₈) and a vinyltrimethoxysilane or a siloxane-containing fluorinated organic compound film deposited by plasma CVD by using, as raw material gas, a gas mixture of C₆F₆ and HMDSO. However, the type of the organic-inorganic hybrid film is not particularly specified.

By way of example, etching is performed in an etching apparatus using a high-density plasma as a plasma source under such conditions that pressure is 30 mTorr, the power of an RF voltage applied to a counter electrode is 3 kW, the power of a bias voltage applied to a sample to be etched is 100 W, the flow rate of ammonia gas is 30 sccm, and the flow rate of fluorine gas is 5 sccm.

In etching an organic-inorganic hybrid film containing an organic component and a silica component, it is necessary to simultaneously etch the plural components of the organic and silica components having different etching properties.

However, there are cases where the silica component cannot be etched by using a plasma derived from an etching gas composed of a gas mixture of oxygen gas, nitrogen gas, and hydrogen gas, an etching gas composed of ammonia gas, or the like, which is used to etch an organic compound film. Consequently, etch residues and particles are generated remarkably and practical etching cannot be performed.

If fluorocarbon used to etch a silicon oxide film is added to the etching gas, the silica component can be etched. In the case of using the silicon oxide film as an etch stopper, however, the problem is encountered that etching selectivity is degraded significantly.

By contrast, if etching is performed by using a plasma derived from an etching gas containing ammonia gas and fluorine gas as main constituents, as in the fifth embodiment, the organic component is decomposed by ammonia gas, similarly to the first embodiment, while the inorganic component is decomposed by fluorine gas, so that etching proceeds. On the other hand, a reaction represented by SiO₂+2F₂→SiF₄↑+O₂ ↑ occurs between SiO₂ (which causes the generation of etch residues and particles) formed by the oxidation of silicon and F₂. contained in the etching gas, so that SiF₄ and O₂ generated are evaporated. This prevents the generation of etch residues and particles.

If the silicon oxide film is formed under the organic-inorganic hybrid film, the amount of fluorine gas to be added is preferably small to achieve satisfactory etching selectivity with respect to the silicon oxide film.

If the power of the bias voltage is reduced and the pressure in the chamber is slightly increased (the degree of vacuum is reduced), there can be performed etching which is more anisotropic with respect to the organic-inorganic hybrid film.

Instead of using the plasma derived from the etching gas containing ammonia gas and fluorine gas as the main constituents, anisotropic etching may also be performed by using a plasma derived from an etching gas containing hydrogen gas and nitrogen trifluoride gas as main constituents, an etching gas containing nitrogen gas, hydrogen gas, and fluorine gas as main constituents, an etching gas containing nitrogen gas and hydrogen fluoride gas as main constituents, or an etching gas containing nitrogen gas and fluorinated hydrocarbon gas as main constituents.

If an extremely small amount of fluorinated hydrocarbon gas is added instead of fluorine gas, highly anisotropic etching can be performed with respect to the organic-inorganic hybrid film without generating etch residues or particles.

### Embodiment 6

A sixth embodiment of the present invention performs anisotropic etching with respect to an interlayer insulating film composed of an organic-inorganic hybrid film by using a plasma derived from an etching gas containing ammonia gas, fluorine gas, and inert gas (such as argon gas) as main constituents.

As an exemplary organic-inorganic hybrid film, there can be listed a siloxane-containing fluorinated organic compound film deposited by plasma CVD by using, as raw material gas, a gas mixture of C₄H₈ (or C₁₀F₁₈) and a vinyltrimethoxysilane or a siloxane-containing fluorinated organic compound film deposited by plasma CVD by using, as raw material gas, a gas mixture of C₆F₆ and HMDSO. However, the type of the organic-inorganic hybrid film is not particularly specified.

By way of example, etching is performed in an etching apparatus using a high-density plasma as a plasma source under such conditions that pressure is 30 mTorr, the power of an RF voltage applied to a counter electrode is 3 kW, the power of a bias voltage applied to a sample to be etched is 100 W, the flow rate of ammonia gas is 30 sccm, the flow rate of fluorine gas is 5 sccm, and the flow rate of argon gas is 20 sccm.

According to the sixth embodiment, the organic component is decomposed by ammonia gas and the inorganic component is decomposed by fluorine gas, similarly to the fifth embodiment, so that etching proceeds. Moreover, SiO₂ and F₂ react with each other to generate SiF₄ and O₂ and the generated SiF₄ and O₂ are evaporated, which prevents the generation of etch residues and particles.

Since inert gas has been added to the etching gas in the sixth embodiment, even if a silicon oxide film is formed under the organic-inorganic hybrid film, satisfactory etching selectivity is achieved with respect to the silicon oxide film.

Instead of using the plasma derived from the etching gas containing ammonia gas, fluorine gas, and inert gas as the main constituents, anisotropic etching may also be performed by using a plasma derived from an etching gas containing hydrogen gas and nitrogen trifluoride gas as main-constituents, an etching gas containing nitrogen gas, hydrogen gas, fluorine gas, and inert gas as main constituents, an etching gas containing nitrogen gas, hydrogen fluoride gas, and inert gas as main constituents, or an etching gas containing nitrogen gas, fluorinated hydrocarbon gas, and inert gas as main constituents.

If an extremely small amount of fluorinated hydrocarbon gas is added instead of fluorine gas, highly anisotropic etching can be performed with respect to the organic-inorganic hybrid film without generating etch residues or particles.

### Embodiment 7

A seventh embodiment of the present invention performs anisotropic etching with respect to an interlayer insulating film composed of an organic-inorganic hybrid film by using a plasma derived from an etching gas containing carbon dioxide gas and fluorine gas as main constituents.

As an exemplary organic-inorganic hybrid film, there can be listed a siloxane-containing fluorinated organic compound film deposited by plasma CVD by using, as raw material gas, a gas mixture of C₄H₈ (or C₁₀F₁₈) and a vinyltrimethoxysilane or a siloxane-containing fluorinated organic compound film deposited by plasma CVD by using, as raw material gas, a gas mixture of C₆F₆ and HMDSO. However, the type of an organic-inorganic hybrid film is not particularly specified.

By way of example, etching is performed in an etching apparatus using a high-density plasma as a plasma source under such conditions that pressure is 5 mTorr, the power of an RF voltage applied to a counter electrode is 3 kW, the power of a bias voltage applied to a sample to be etched is 300 W, the flow rate of carbon dioxide gas is 20 sccm, and the flow rate of fluorine gas is 5 sccm.

According to the seventh embodiment, CO ions generated from carbon dioxide gas contribute to the etching of the organic component, similarly to the fourth embodiment, and fluorine gas contributes to the etching of the inorganic component, similarly to the fifth embodiment, so that etching proceeds with respect to the organic-inorganic hybrid film. Moreover, etch residues and particles are not generated for the same reasons as described above.

If inert gas such as argon gas is added to the etching gas, both the anisotropic property of etching and the etching rate can be improved.

If an extremely small amount of fluorinated hydrocarbon gas is added instead of fluorine gas, highly anisotropic etching can be performed with respect to the organic-inorganic hybrid film without generating etch residues or particles.

### Embodiment 8

An eighth embodiment of the present invention performs anisotropic etching with respect to an interlayer insulating film composed of an organic-inorganic hybrid film by using a plasma derived from an etching gas containing carbon monoxide gas and fluorine gas as main constituents.

As an exemplary organic-inorganic hybrid film, there can be listed a siloxane-containing fluorinated organic compound film deposited by plasma CVD by using, as raw material gas, a gas mixture of C₄H₈ (or C₁₀F₁₈) and a vinyltrimethoxysilane or a siloxane-containing fluorinated organic compound film-deposited by plasma CVD by using, as raw material gas, a gas mixture of C₆F₆ and HMDSO. However, the type of an organic-inorganic hybrid film is not particularly specified.

By way of example, etching is performed in an etching apparatus using a high-density plasma as a plasma source under such conditions that pressure is 5 mTorr, the power of an RF voltage applied to a counter electrode is 3 kW, the power of a bias voltage applied to a sample to be etched is 300 W, the flow rate of carbon monoxide gas is 20 sccm, and the flow rate of fluorine gas is 5 sccm.

According to the eighth embodiment, CO ions generated from carbon monoxide gas contribute to the etching of the organic component and fluorine gas contribute to the etching of the inorganic component, so that etching proceeds with respect to the organic-inorganic hybrid film. In addition, etch residues and particles are not generated for the same reasons as described above.

According to the eighth embodiment, in particular, the amount of active oxygen generated in the plasma derived from carbon monoxide gas is smaller than that generated in a plasma derived from carbon dioxide gas. On the other hand, generated carbon ions protect the sidewalls of the depressed portion formed by etching and remove excess oxygen. For such reasons, the oxidation of the organic component is further suppressed.

If inert gas such as argon gas is added to the etching gas, both the anisotropic property of etching and the etching rate can be improved.

If an extremely small amount of fluorinated hydrocarbon gas is added instead of fluorine gas, highly anisotropic etching can be performed with respect to the organic-inorganic hybrid film without generating etch residues or particles.

Although argon gas has been used as inert gas in each of the foregoing embodiments, neon gas, xenon gas, or a gas mixture thereof may also be used instead.

What is claimed is:

1. An etching method comprising the step of performing anisotropic etching with respect to an interlayer insulating film composed of an organic-inorganic hybrid film containing an organic component and a silica component by using a plasma derived from an etching gas containing a H₂ gas, a N₂ gas, and a F₂ gas, but no component which oxidizes the organic component.

2. The etching method of claim 1, wherein said etching gas contains an inert gas.

3. An etching method comprising the step of performing anisotropic etching with respect to an interlayer insulating film composed of an organic-inorganic hybrid film containing an organic component and a silica component by using a plasma derived from an etching gas containing a H₂ gas and a nitrogen trifluoride gas, but no component which oxidizes the organic component.

4. The etching method of claim 3, wherein said etching gas contains an inert gas.

5. An etching method comprising the step of performing anisotropic etching with respect to an interlayer insulating film composed of an organic-inorganic hybrid film containing an organic component and a silica component by using a plasma derived from an etching gas containing a N₂ gas and a fluorinated hydrocarbon gas as main constituents, but containing no O₂ gas as a component.

6. The etching method of claim 5, wherein said etching gas contains an inert gas.

7. An etching method comprising the step of performing anisotropic etching with respect to an interlayer insulating film composed of an organic-inorganic hybrid film containing an organic component and a silica component as main constituents by using a plasma derived from an etching gas containing a carbon dioxide gas and a fluorine gas as main constituents.

8. The etching method of claim 7, wherein said etching gas contains an inert gas.

9. An etching method comprising the step of performing anisotropic etching with respect to an interlayer insulating film composed of an organic-inorganic hybrid film containing an organic component and a silica component as main constituents by using a plasma derived from an etching gas containing a carbon dioxide gas and a fluorinated hydrocarbon gas as main constituents.

10. The etching method of claim 9, wherein said etching gas contains an inert gas.

11. An etching method comprising the step of performing anisotropic etching with respect to an interlayer insulating film composed of an organic-inorganic hybrid film containing an organic component and a silica component as main constituents by using a plasma derived from an etching gas containing a carbon monoxide gas and a fluorinated gas as main constituents.

12. The etching method of claim 11, wherein said etching gas contains an inert gas.

13. An etching method comprising the step of performing anisotropic etching with respect to an interlayer insulating film composed of an organic-inorganic hybrid film containing an organic component and a silica component as main constituents by using a plasma derived from an etching gas containing a carbon monoxide gas and a fluorinated gas as main constituents.

14. The etching method of claim 13, wherein said etching gas contains an inert gas.
